(19) United States
(12) Patent Application Publication
(10) Pub. No.: US 2025/0239777 A1
(43) Pub. Date: Jul. 24, 2025

(54) WIRELESS MICROPHONE DIPOLE RF ANTENNA

(71) Applicant: Sound Devices LLC, Reedsburg, WI (US)

(72) Inventors: Matthew G. Anderson, Madison, WI (US); Jason McDonald, Madison, WI (US); Mirhamed Mirmozafari, Waunakee, WI (US); Andrew Robinson, Modbury (GB)

(73) Assignee: Sound Devices LLC, Reedsburg, WI (US)

(21) Appl. No.: 19/032,311

(22) Filed: Jan. 20, 2025

Related U.S. Application Data
(60) Provisional application No. 63/622,775, filed on Jan. 19, 2024.
(60) Provisional application No. 63/722,568, filed on Nov. 19, 2024.

(51) Int. Cl. H01Q 9/28; H01Q 1/22; H03F 3/19; H04R 1/08; H04R 1/32; H04R 3/00

(52) U.S. Cl. CPC H01Q 9/28; H01Q 1/22; H04R 1/083; H04R 1/326; H04R 3/00; H03F 3/19; H03F 2200/451; H04R 2420/07

(57) ABSTRACT

A handheld wireless microphone has improved resilience against intermittent dropouts due to the placement of hands on the body of the handheld wireless microphone. A robust, dipole RF antenna is provided in the body of the handheld microphone. One antenna element is a conductive cone or truncated cone at the bottom of the microphone body, which is surrounded by a conductive cup and an insulated gap layer to form a capacitive coupling configuration that mitigates interference of RF radiation by human flesh. The other antenna element is conductive and serves as the frame of the microphone body.

### CROSS-REFERENCE TO RELATED APPLICATION

The present application claims priority to prior U.S. Provisional Patent Application Nos. 63/622,775 filed Jan. 19, 2024, and 63/722,568 filed Nov. 19, 2024, which are assigned to the same entity as the present invention.

### FIELD OF THE INVENTION

The disclosed invention pertains to antenna reliability and the transmission of audio data from digital wireless handheld microphones. The invention uses a biconical RF antenna in the body of the microphone, which delivers continuity of data transmission with robust resistance to interference that can be caused by placement of a user's hands over RF antennas in prior art wireless microphones. The invention also pertains to the insertion of removable counterweights or an inertial mass in a microphone using the biconical RF antenna. Selecting different counterweights may be useful to enhance ergonomics and balance of the handheld microphone especially if other microphone components are interchanged and change the center of mass.

### BACKGROUND

Due to the high degree of convenience and freedom they offer for movement, the use of wireless microphones has seen a dramatic increase in use over the last several years with many new products being successfully marketed. Aside from the convenience of eliminating the corded connection, not all wireless microphones are created equal. Wireless microphones typically function by internally digitizing an analog audio signal representing the detected sound and wirelessly transmitting the digital audio data to some form of a receiving station. In order to properly receive digitized audio data, a persistent radio-frequency (RF) pathway must exist between the microphone transmitter and the receiving station and the RF pathway must allow for the propagation of electromagnetic (radio) waves at a sufficient power level, bandwidth and signal-to-noise ratio (SNR) to sustain the transfer of the digital audio data.

A common problem encountered when using wireless microphones is the intermittent obstruction of the transmitting antenna that results when a performer happens to place their hand (or hands) over the portion of the microphone capsule containing the transmitting RF antenna. Placing a hand over the microphone capsule obstructs the RF pathway and may reduce the received power and the SNR at the RF receiving station. A dropout may occur if the fidelity of signal received by the receiving station is interrupted. During live performances, dropouts are often blatantly noticeable to the audience and degrade the overall quality of the performance. This problem is especially troublesome for performers with larger hands who may be more prone to cover a transmitting RF antenna for a longer period of time. This problem is severe and has become so well known in the industry that the phrase “death grip” has become a popular way of referring to this condition. In accordance, the phrase “death grip condition” is used throughout this disclosure to describe a condition when the transmitting RF antennas on a wireless microphone have been rendered ineffective due to the proximity of a performer's hands while in use.

With regard prior attempts at remedying the death grip condition, reference is made to U.S. Pat. No. 9,742,459 B2 entitled “Electronic Device Having Sensors and Antenna Monitor for Controlling Wireless Operation” by Ayala Vazquez et al., issuing Aug. 22, 2017. This patent describes a wireless device wherein tunable components of a wireless antenna may be tuned in response to the output of proximity sensors designed to detect an external obstruction for one or more transmitting RF antennas. The '459 patent describes the use of measuring antenna impedance as a means to detect the presence of a blocking (or obstructing) object, such as a human hand. However, even when a wireless microphone is equipped with two transmitting antennas, a death grip condition can occur due to a performer placing one hand over each of the two antennas at the same time.

The ability of professional entertainers to provide a performance experience that meets the expectations of audiences (and themselves) can be affected by nuances of the microphones they employ while on stage. Through the course of their professional careers, performers and particularly singers may become accustomed to and learn to work with a microphone having specific characteristics. These characteristics may include the audio directional (gain) pattern for voice detection or the weight and balance of the microphone assembly that a user becomes accustomed to, while actively performing or dancing (on stage). These characteristics are important so that the performer can reliably move and orient the microphone to provide consistent acoustic quality. For this reason, performers often opt to use their own privately owned microphones to which they have become accustomed. Unfortunately, the logistics of stage settings do not always facilitate the selective use of a personal microphone on an individual basis.

When a personalized microphone cannot be used, it can be desirable nevertheless that the microphone used possess similar weight and balance attributes as expected by users based on their prior experience. For example, if a user interchanges a microphone head for another having a different mass, the center of mass as measured along the longitudinal axis of the microphone will shift. If, while in use, a user swings the microphone from left to right while singing and/or dancing, an unexpected change in center of mass may result in the microphone rotating (off axis) while in motion. If a user is not anticipating a change in weight and balance of a microphone assembly, they might not properly compensate to maintain the orientation of the microphone head with respect to the location for their voice. This may be of particular importance in situations where a microphone has a directional pattern associated with it, such as a cardioid pattern that may be present if a ribbon type microphone head is employed.

### SUMMARY OF THE INVENTION

The invention described in this disclosure overcomes the limitations described above by including a transmitting RF antenna that is designed to accommodate the presence of human hand placed over it and still maintain sufficient RF energy output to preserve the efficacy of the RF communication link even when a performer handles the microphone in a manner that would likely produce a death grip condition with traditional antenna designs.

A handheld wireless microphone constructed in accordance with the invention has a dipole transmitter RF antenna with two conductive elements. The lower conductive antenna element is in the shape of a cone or truncated cone and a conductive microphone frame serves as an upper conductive antenna element. The combined length of the two antenna elements, preferably, extends substantially over the entire length of the microphone body. The lower conductive antenna cone is preferably made of conductive gold-plated brass. An RF amplifier contained within the microphone body is connected to a first antenna feed-point on the lower conductive antenna cone and to a second antenna feed-point on the conductive frame. The RF amplifier commonly supplies oscillating electrical energy in opposing polarity to the feed-points causing the antenna to radiate an RF electromagnetic waveform capable of carrying information to an RF receiver.

A conductive cup, preferably a metal cup, surrounds the lower conductive antenna cone and an insulating layer is located between the metal cup and the lower conductive cone. A capacitive coupling exists between metal cup and the lower antenna cone. It is desirable that antenna be effective across a frequency range of 470 MHz to 1525 MHz. The capacitance between the wide end of the lower antenna cone and the metal cup enhances the frequency bandwidth of the antenna particularly at the lower end of the desired frequency range, e.g. improves antenna resonance at 470 MHz.

The metal cup also acts as a barrier against the disturbance of antenna currents that may be caused by the presence of a hand wrapped around the lower end of the microphone body in the absence of the metal cup. In this way, the metal cup also significantly mitigates a death grip condition. If the microphone were held with a hand placed at the bottom end of the microphone body absent the metal cup, capacitive coupling between the hand and the antenna would cause resistive losses and interfere with electromagnetic currents in the antenna. However, when the user holds over the metal cup rather than directly over the antenna cone, the excited current on the antenna cone is not significantly changed. The metal cup is positioned with a gap from the antenna cone creating a capacitive barrier that dampens and alleviates the impact of covering the antenna with the hand.

It is desired that the antenna elements extend longitudinally substantially the entire length of the microphone body. Microphone components can be located within the lower antenna cone or the conductive frame without interfering with the radiative capability of the antenna. When the microphone body is held in hand, only a portion of the dipole antenna is covered, ensuring that the dipole antenna retains its radiative capabilities. A circular symmetry exists for the lower antenna cone, and it is preferred the conductive frame also provides substantially circular symmetry such as with a cylinder or cone shaped frame. As such, the directional pattern for radiation emitted by the dipole antenna has circular symmetry. The result is a circular doughnut-shaped directivity pattern where an equal radiation intensity results regardless of the radial direction about the longitudinal axis of the handheld microphone body. A further advantage of this invention is that, if the microphone head is omnidirectional, the microphone can be used without any concern of the radial orientation of the microphone while in use.

In one exemplary embodiment of the invention, the microphone body comprises a plastic outer shell, e.g. ornamental plastic, that fits over the conductive frame forming the second clement of the dipole RF transmitter antenna. The microphone body contains not the antenna components (including the conductive cup), but also the RF amplifier and other electronics for processing and transmitting the signal from the microphone head, for controlling the microphone settings, for providing power, for communicating via wireless with an app on a smartphone, table or PC (e.g. via Bluetooth), for communicating via a dedicated wireless back channel with other devices in the sound system (e.g. a dedicated 2.4 GHz bidirectional communication link), or for communicating with other devices via a wired connection when off line (e.g. a USB-C port that can be used during set up). In a second exemplary embodiment of the invention, a plastic (polycarbonate) screw cover is provided at the lower end of the microphone body which enables the bottom of the microphone body to be opened when not in use. In this embodiment, a balancing counterweight, e.g. cone shaped, can be placed within the antenna cone at the lower end of the microphone body. The screw cover retains the balancing weight snugly within antenna cone at the lower end of the microphone body, although other types of retaining caps can be used with the spirit of the invention. The balancing counterweight is preferably removable such that it may be removed and interchanged with another balancing weight having a different mass, depending on the preferences of a user. In this embodiment, the conductive (metal) cup is preferably embedded in the plastic screw cover or retainer cap, and plastic on the screw cover (or retainer cap) inside of the embedded conductive (metal) cup serves as the insulation layer described above to facilitate the capacitive coupling of the conductive (metal) cup and the conductive antenna cone.

In the exemplary embodiments of the invention, the user or sound engineer is able to set the RF frequency, e.g., from 470 MHz to 1525 MHz in 25 kHz steps, and the RF transmission power, e.g., 2 mW (low power), 10 mW (normal), 20 mW (high), 40 mW (very high), or 100 mW (extra high). It is recommended to use the lowest RF power that gives the desired range. The lower the set RF power output, the longer the battery run time. These settings and others can occur via controls and a display on the microphone, via a Bluetooth connection with an app on a smartphone, tablet or PC, or through a dedicated bidirectional communication link with the receiver or other associated sound equipment, e.g. a dedicated 2.4 GHz bidirectional wireless data link.

A more complete appreciation of the present invention and the attendant advantages and features thereof will be more readily understood by reference to the following detailed description when considered in conjunction with the accompanying drawings.

### BRIEF DESCRIPTION OF THE DRAWINGS

FIG. 1 is schematic side view of a digital wireless microphone constructed in accordance with a first exemplary embodiment of the invention, cutaway in part to show components of the antenna.

FIG. 2 is a cross-sectional view of the components in the microphone body shown in FIG. 1.

FIG. 3 is a schematic drawing illustrating an RF amplifier connected to antenna feedpoints in the wireless microphone body.

FIG. 4 illustrates how a reversable microphone head adapter may be configured to attach a selected microphone head type for a handheld wireless microphone according to one exemplary embodiment of the invention.

FIG. 5 is a diagram illustrating electrical components of a wireless microphone implementing the exemplary embodiment of the invention.

FIG. 6 illustrates a lower portion of the microphone having an antenna constructed in accordance with a second exemplary embodiment of the invention.

FIG. 7 is a partial assembly drawing pertaining to the second exemplary embodiment of the invention showing a screw-on cover removed and a counterweight (inertial mass) with a conical shape configured to be inserted into the lower antenna cone.

FIG. 8 illustrates the second exemplary embodiment of the invention with the conical counterweight inserted into the lower antenna cone in the microphone body and the screw-on cover yet to be attached.

### DETAILED DESCRIPTION THE INVENTION

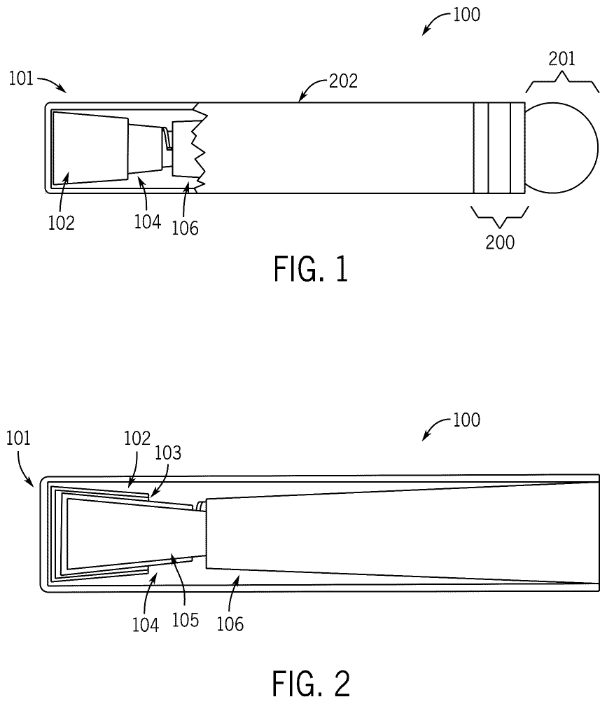

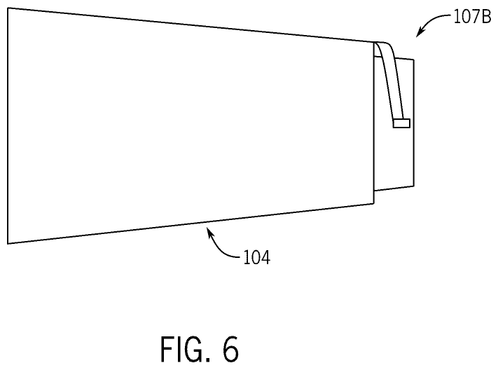

FIGS. 1 through 5 illustrate a first exemplary embodiment of the invention. FIGS. 6 through 8 illustrate modifications pertaining to a second exemplary embodiment of the invention.

Referring to FIG. 1, the handheld wireless microphone 100 generally has a microphone head 201, a microphone body 202 and a head connection adapter 200. The microphone head 201 includes one or more diaphragms and associated electronics to sense acoustic pressure. The internal electronics of the microphone head 201 are normally responsible for many aspects of the microphone frequency response and its directionality profile. The main body 202 of the microphone 100 is surrounded by an outer sleeve or shell 101 which is made of plastic and is removable. The microphone 100 shown in FIGS. 1 and 2 has a substantially continuous plastic outer shell 101 that covers substantially the entire microphone body 202 including the bottom end of the microphone body 202 opposite the microphone head 201. The microphone body 202 generally contains a battery, signal amplification and analog-to-digital converting circuitry, digital signal processing and RF electronics including those for driving the wireless RF transmitter antenna. It is common that the transmitting antenna be located at the bottom of the microphone body 202 and surrounded by a protective chamber which is sometimes referred to as the antenna capsule. However, in accordance with the invention, the antenna is a dipole antenna that includes a conductive antenna cone (or truncated cones) 104 and a conductive frame 106 for the microphone body 202. The conductive frame 106 serves as a second antenna element. The combination of the conductive antenna cone 104 and the conductive frame 106 extending essentially along the entire microphone body 202 within the outer shell 101 of the microphone body 202. Accordingly, the entire length or substantially the entire length of the microphone body 202 serves as a long omni-directional radiative element, thereby substantially avoiding dropouts caused by the death grip.

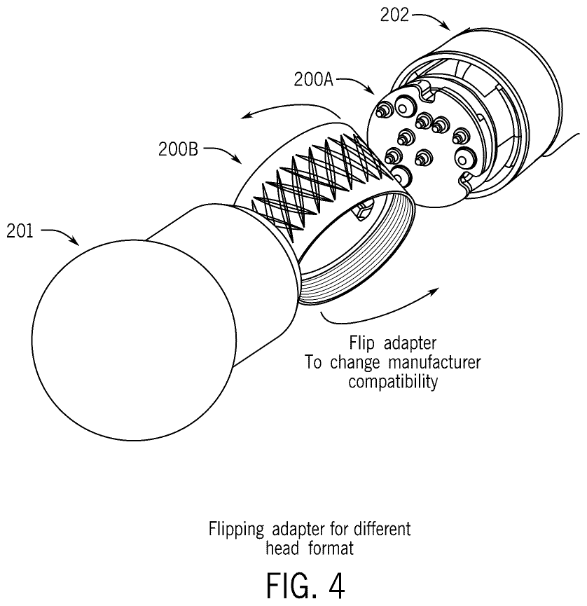

An exemplary head connection adapter 200 is described in co-pending application Ser. No. 18/755,831 entitled “Microphone Head Connector Adapter,” by Matthew Anderson and Jason McDonald, filed on Jun. 27, 2024 and assigned to the assignee of the present application, the content of which is also incorporated herein by reference in its entirety. Briefly, the microphone head connection adapter 200 has a reversible collar ring 200B that facilitates mechanical and electrical connection between the bottom of the respective microphone head 201 and the top of the microphone body 202. In the exemplary embodiment of the invention as illustrated in FIG. 4, the main body 202 is configured to physically accommodate the reversible head connection adapter 200 and multiple types of microphone heads 201. In other words, it is contemplated that the same wireless microphone body 202 (and antenna elements 104, 106) be used with different types and sizes of microphone heads 201 which may, and will in many cases, have different weight, dimensions, frequency response and directionality. The type of interconnection for respective microphone head 201 is determined by the (up/down) orientation of a collar ring 200B forming a part of the microphone head connection adapter 200. The pins on board 200A are configured to detect head type as described in co-pending application Ser. No. 18/755,831 entitled “Microphone Head Connector Adapter.”

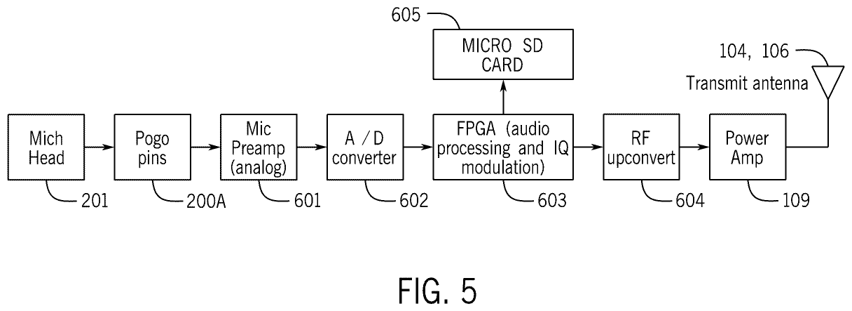

Referring briefly to FIG. 5, exemplary electrical components of the wireless microphone 100 are illustrated to show the flow of audio data through the microphone. The microphone head 201 generates an analog audio signal which is transmitted from the head to the assigned connection pins 200A on the body 202 of the microphone 100, in accordance with FIG. 4 as described above. From the pins 200A, the analog audio signals are amplified through an analog preamplifier 601, and then digitized by an analog-to-digital converter 602. The digitized audio signals are processed in a microcontroller which in FIG. 5 is a field programmable gate array (FPGA) 603. The FPGA 603 implements audio processing and IQ modulation. The processed digital output from the FPGA 604 is RF upconverted 604 and amplified 109, and then fed to the feedpoints 107A, 107B to antenna cones 106, 104 for radio transmission to a receiver. Although not shown in FIG. 5, the microphone body 202 also includes a battery and power conversion and charging electronics. FIG. 5 also shows that memory such as a removable micro SD card 605 can be included on the microphone body 202, e.g. to store digital audio data.

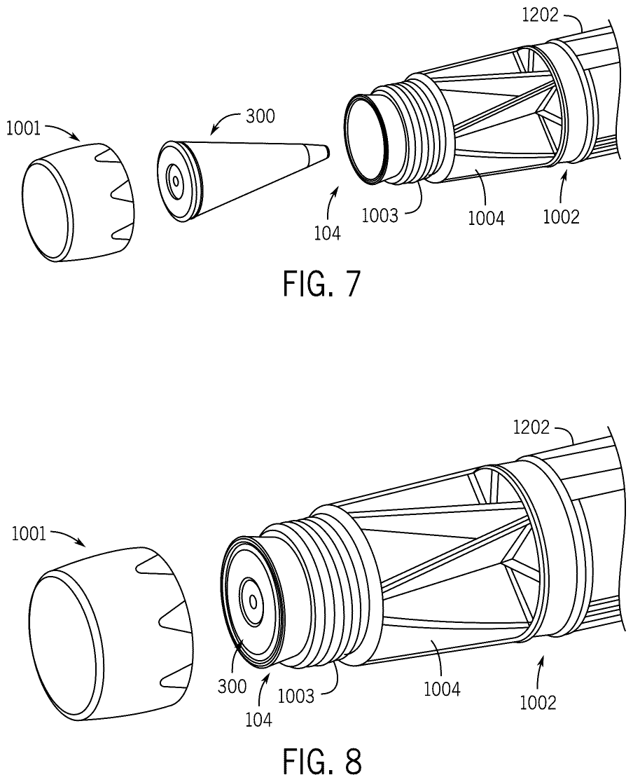

Referring again to FIG. 2, the RF transmitter antenna is dipole antenna having two conductive elements 104, 106 commonly driven in opposing polarity for radiating an electromagnetic waveform capable of carrying information to a receiver. The lower conductive element 104 is a cone or truncated cone 104, and the preferred material is gold-plated brass but other conductive metals should be suitable. The microphone frame 106 serves as the upper antenna element in the dipole antenna. In FIGS. 1 and 2 the lower antenna cone 104 is a truncated cone. In the embodiment depicted in FIGS. 6-8, however, the narrow end of the cone is much closer to being a full cone, e.g. the cone length is 47.7 mm, the cone taper is 11.25 degrees and the outer cone diameter on the wide end (bottom) is 20.2 mm. The antenna design provides several important advantages over the prior art. The antenna elements may be housed completely inside the plastic outer shell 101, and other required components such as batteries, power supplies, audio processing and control electronics can be contained in the conductive fame 106 whereas a conical counterweight 300, see FIG. 7 can be contained in the lower conductive antenna cone 104.

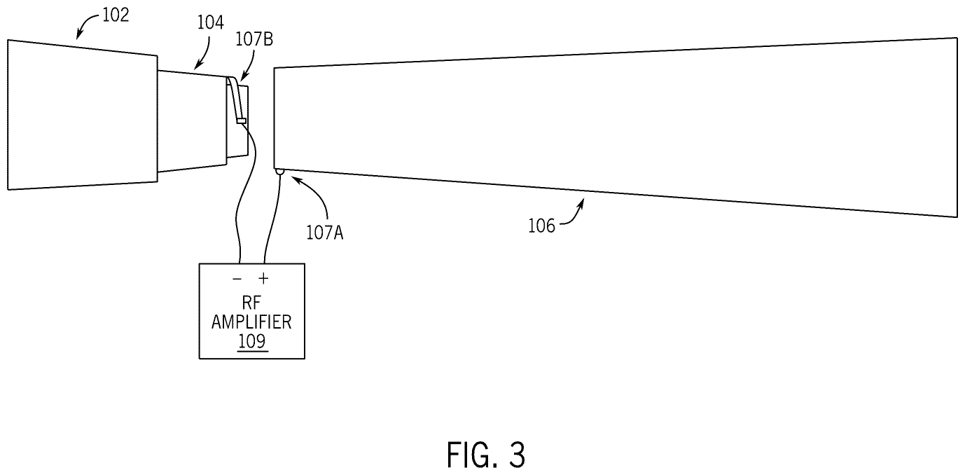

FIG. 3 illustrates the two antenna elements 104 and 106 connected to the output of an RF amplifier 109 according to the exemplary embodiment of this invention. The upper antenna clement 106 which is also a conductive frame for the microphone body 202, is in the form of a truncated cone 106 in the depicted embodiment. The conductive frame 106 does not need to be cylindrical, e.g. it can be cylindrical or substantially cylindrical. It is preferred that conductive frame 106 have circular symmetry around the longitudinally axis of the frame 106. The conductive frame 106 is made of a conductive material such as machined or cast aluminum, copper, steel, etc. The conductive frame 106 is located inside the plastic outer shell 101 and enables other microphone components to be mounted within the frame 106, without substantially affecting the performance of the frame 106 as an antenna component. Additional microphone elements such as batteries, audio electronics and the RF amplifier 109 can be housed internally to the conductive frame 106. The base of the conductive frame 106 is connected at the first feedpoint 107A to an output from the antenna RF amplifier 109. The base of the lower conductive cone 104 is connected at the second feedpoint 107B to the also be driven by the output from the dipole antenna RF amplifier 109. The base of the lower antenna cone 104 and the base of the conductive frame 106 are physically separated but in close proximity to one another. The physical separation enables there to be a relative potential difference or voltage difference between the lower antenna cone 104 and the conductive frame 106. In this sense, the conductive frame 106 serves as an antenna relative ground or reference. As shown best in FIG. 2, the lower antenna cone 104 is mounted on an insulated substrate 105. Although (for the sake of clarity), FIG. 3 shows the RF amplifier as external to the conductive frame 106, in preferred embodiments for the invention, the RF amplifier 109 is internally housed within the conductive frame 106.

As mentioned, supporting electronics (such as batteries, power supplies, amplifiers, RF communications and digital audio processing) may be designed to reside within the conductive frame 106 that is itself fully contained within the outer shell 101. Furthermore, both antenna elements 106 and 104 may be contained within the same exterior housing 101 as shown in FIGS. 1 and 2. This configuration allows the exterior housing/outer shell 101 to be constructed without the need to include any abrupt transitions (such as extending covers, bulbs or projections) or other means to deter users from holding it in any particular position or pattern. These design features provide the opportunity for a smooth and sleek exterior profile that maximizes ergonomic utility. The outer shell 101 may be constructed of molded plastic, fiberglass or other attractive, durable, comfortable and nonconductive material. The result is a microphone exterior that is pleasing to the user and ergonomic which can be important when the microphone is used for longer periods of time.

The conical shape of the lower antenna cone 104 provides smooth transition and tapering, which supports the ultra-wideband operational frequency bandwidth (470 MHz to 1525 MHz) and other critical operational features. The lower cone 104 functions as one pole of a dipole antenna, and the conductive frame 106 in the body 202 of the microphone serves as the opposite pole. The feedpoint 107B at the narrow end of the cone 104 is suitable for dipole excitation. The wide end of the lower cone 104 is parasitically coupled to a conductive (metal) cup 102 embedded in the lower antenna capsule. This coupling creates a large capacitance between the wide end of the cone 104 and the metal cup 102, enhancing frequency bandwidth of the antenna 104, 106. Referring to the embodiment shown in FIG. 2, the lower conductive antenna cone 104 is mounted on an insulated antenna substrate 103. The conductive cup 102 is incorporated around the radiative element (cone) 104. This metal cup 102 is electrically isolated from the metal antenna cone 104 by an insulated cup substrate 103 (e.g. 1 to 2 mm thick plastic). Given the small distance between the metal cup 102 and metal antenna cone (radiative element) 104, a capacitive coupling exists between metal cup 102 and the metal antenna cone 104.

The metal cup 102 acts as a barrier in preventing the disturbance of antenna currents that may be caused by the presence of a hand wrapped around the lower base of the outer shell 101. Absent the metal cup 102, the capacitive coupling between the hand and antenna can cause resistive losses through the human flesh.

Accordingly, the metal cup 102 serves two important purposes. First, the metal cup 102 enlarges the effective dimensions of the antenna, thereby reducing the lower cutoff frequency of the antenna's response. This is particularly important as the 470 MHz band is an important frequency to transmit, and the metal cup 102 enhances the antenna's resonance at this frequency. Second, the metal cup 102 significantly mitigates the death grip effect. The metallic cup 102 is positioned with a gap (103) from the antenna cone 104, thereby acting as a capacitor that dampens the impact of covering the antenna. When a user's hand is placed over the lower antenna cone 104, the user's hand is actually placed over the metal cup 102 rather than directly over the antenna cone 104. The excited current on the antenna cone 104 is not significantly changed by the hand covering the metal cup 102.

When the microphone 100 is held in hand, only a portion of the dipole antenna 104, 106 is covered, ensuring that the dipole antenna 104, 106 retains its radiative capabilities. As can be seen from the diagrams in FIGS. 1 and 2, a circular symmetry exists for both elements 104, 106 of the dipole antenna. As such, the directional pattern for radiation emitted by the dipole antenna also exhibits a circular symmetry. The result is a circular doughnut shaped directivity pattern where an equal radiation intensity results regardless of the radial direction about the longitudinal axis of the handheld microphone body 202. A further advantage of this invention is that, if an omnidirectional microphone head 201 is selected by the user, the microphone 100 can be used without any concern of the radially orientation of the microphone 100.

By applying a differential voltage potential to the lower radiative element 104 relative to the microphone frame 106, the entire length of the microphone serves as a (longer) radiative element, improving the efficiency by creating a more resistive (real valued input impedance) for the antenna. Another advantage of this invention arises from tapering the lower radiative element 104 resulting in a transition from a narrow current path to a wider one. These design features increase the useable bandwidth for the antenna. Laboratory tests have shown this antenna is effective across a frequency range of 470 MHz to 1525 MHz. This is especially beneficial at lower frequencies (470 MHz) where the wavelength is longer. Having a predominately real input impedance allows for the omission of an impedance matching circuit between output of the RF amplifier 109 and feed-points to the dipole antenna 107A, B. Since impedance matching circuits are typically parasitic, removing the requirement for this circuit can typically improve the output for the antenna by about 1 to 2 dB in addition to cost savings with a simpler design.

Experiments and testing have shown that while a 20 dB reduction in radiated power may occur for traditional antenna designs in a death grip condition, the present invention typically reduces those losses to under 6 dB. Experimental testing using a 200 kHz wide BPSK transmission have shown that audio communication with a wireless microphone can be maintained with this invention regardless of a (one or two hand) death grip condition being placed anywhere on the microphone shell 101 while in use.

FIGS. 6, 7 and 8 show a lower end of the microphone body 1202 configured in accordance with a second exemplary embodiment of the invention. The embodiment of the invention depicted in FIGS. 7 and 8 includes a weighted conical insert 300. The weighted conical insert 300 can be replaced by a different weighted conical insert 300 to adjust the weight and the balance of the microphone. For example, referring to FIG. 4, the microphone may include a removable microphone head adapter 200A, 200B that may be affixed to a microphone body 202, 1202, where the orientation of the adapter collar 200B may be set to accommodate the subsequent attachment for different microphone heads 201 that may have different dimension and weight. In the event of changing one microphone head 201 for another, there is normally a change in the center of mass for the microphone. Microphone heads are typically a heavier component on a wireless handheld microphone assembly. So even in cases where no substitution of the microphone head is made, the center of mass for the handheld microphone assembly is typically toward the top of the assembly. In many cases, users may prefer that this center of mass is more centrally located toward the middle of the assembly, preferably near where it is griped by the user's fingers while in use.

Referring to FIGS. 6, 7 and 8, due to what is commonly referred to as the skin effect at RF frequencies, placing an object into the interior of the lower antenna cone 104 does not significantly affect the function of the dipole antenna. In fact, the function for the dipole antenna is maintained even if the object placed into the interior of the lower cone 104 is itself made of a conductive material. FIG. 6 shows an isolated view for the antenna cone 104, and as indicated the cone 104 is hollow, which allows for insertion of the counterweight 300. A significant amount of mass can be added to the lowest portion of the handheld wireless microphone by constructing a conical insert 300, as illustrated in FIG. 7. In FIG. 8, the weighted conical insert 300 is shown fully inserted into the antenna cone 104 at the lower end of the frame 106 in a microphone assembly 300. The amount of added weight can be varied depending on the density of material and shape used to construct the counterweight insert 300. For example, brass may be preferred for some embodiments as it is inexpensive, easily machined and provides a density of about 8.73 g/cm³. If less mass is desired, a lighter material such as aluminum or magnesium can be used or the shape of the conical insert 300 can be truncated or hollowed to reduce mass. Higher mass inserts may also be constructed using denser materials such as lead (11.34 g/cm³), osmium (22.59 g/cm³), iridium (22.56 g/cm³) or tungsten (19.3 g/cm³). An advantage of tungsten is that it is relatively low cost while providing a very high density. However, due to difficulties in machining it, for some embodiments, it may be preferable (or more cost effective) to use a mixture of epoxy resin and powered tungsten, where the ratio of tungsten to epoxy resin mix is adjusted to achieve a desired density.

As shown in FIGS. 7 and 8, a screw cover 1001 is threaded onto threads 1003 on the bottom of the microphone body 1202. The screw cover 1001 presses the conical counterweight 300 tightly against the inside of the lower cone 104 to hold the weight 300 in place without rattling during use. For some embodiments, it may be desired to pack the end of the screw cover 1001 with compressive foam that will compress against the conical weight 300. Other kinds of retainer caps, other than screw caps, may be suitable to implement the invention as should be apparent to those skilled in the art.

It is desired that a shielded coax cable (not shown) be connected between the feedpoint 107B on the lower cone 104 and a printed circuit board transmitting signals from the RF amplifier 109. The coax cable can be soldered at the feedpoint 107B on the lower cone 104. The shield is connected to the feedpoint 1078A for the conductive frame 106 (or the conductive frame 106) serving as a relative ground reference. Another cable (not shown) that is not shielded is connected (soldered) to the feedpoint 107A on the conductive frame 106. The microphone body 1202 includes a trussed section 1004 which has a conical support wall configured to fit the lower metal cone 104 of the dipole antenna. Double-side pressure sensitive adhesive can be used to mount the lower cone 104 against the inside of the conical support wall of the trussed section 1004. Mounting the lower cone 104 to the microphone body 1202 from the outside of the cone leaves the inside of the cone open to receive the weighted conical insert 300. In addition, it should be noted that the metal cup 102, see FIGS. 1-3, is embedded within the screw cover 1001 shown in FIGS. 7 and 8. The screw cover 1001 also provides the insulated layer or gap serving the same purpose as the insulated cup substrate 103 shown in FIG. 2.

The dimensions of the lower antenna cone 104 (20.2 mm wide diameter, 11.25 degree taper, 47.7 mm length) discussed above are exemplary, but have been found to be particularly effective. Those skilled in the art will recognize that other dimension may be suitable to implement the invention.

Even though this disclosure focused on a conically shaped weights, other shapes (weights) may easily be designed to contact the interior of the antenna cone at a set of points such that they provide for a stable mounting within it. Furthermore, for some embodiments it may be even advantageous to construct series of stackable cones that interlock or connect by threaded stubs to allow a user to stack them to a desired mass before they are placed into the interior of the antenna cone. In addition to mixing a heavy powder with epoxy resin, similar results may be achieved by mixing a granulated (or finely beaded) mixture of a high-density material with epoxy resin that is molded (or cast) to fit into the antenna code without the need for machining.

In one exemplary embodiment, the user or sound engineer can set the RF frequency, e.g., from 470 MHz to 1525 MHz in 25 kHz steps, and the RF transmission power, e.g., 2 mW (low power), 10 mW (normal), 20 mW (high), 40 mW (very high), or 100 mW (extra high). It is recommended to use the lowest RF power that provides the desired range. The lower the RF power, the longer the battery run time.

As mentioned above, the microphone body 202 desirably contains memory or accommodates the use of a removable micro SD card, see FIG. 5, box 605. For example, the microphone 100 can be configured to record 32-bit float Broadcast WAV or RF64 WAV audio files at, e.g., a 48 kHz sampling rates. The high dynamic range gain technology disclosed in Applicant's U.S. Pat. No. 9,654,134, by Popovich et al., entitled “High Dynamic Range Analog-to-Digital Conversion with Selective Regression Based Data Repair,” is desirably used to avoid the need to set gain at the microphone. In record mode, the recorded audio files are stamped with a start time code. Microphone electronics are desirably jammed to be in sync with the receiver. The time stamped audio recordings can be accessed at a later time or even transmitted during live transmission in the event that a drop out is detected at the receiver.

The construction and arrangement for elements of systems and methods as shown in this disclosure for the exemplary (and alternative) embodiments are illustrative only. Given the preceding disclosure, those skilled in the art who review this disclosure will readily appreciate that many modifications are possible without materially departing from the novel teachings and advantages of the subject matter disclosed. For example, in some embodiments placing a radiative element at the top of a handheld microphone may be feasible. Furthermore, for some embodiments radiative elements may not need to possess circular symmetry or may be reconfigurable based on controlled analog circuitry. In addition to capacitive coupling of a lower cone dipole radiating element, performing such methods on other portions of antenna designs (possibly containing multiple antennas or an antenna with more than two radiative elements) may also prove suitable for some embodiments and these are also to be considered as having been envisioned by this disclosure.

1. A handheld wireless microphone comprising:
a dipole RF antenna contained within a microphone body, said dipole RF antenna having with a first conductive element and a second conductive element commonly driven in opposing polarity for radiating an electromagnetic waveform capable of carrying information to a receiver, wherein the first conductive element is a cone or a truncated cone, the narrow end of the first conductive element is separated but in close proximity to the second conductive element, and the first conductive element and the second conductive element extend along a longitudinal axis of the microphone body and with a wide end of the cone or truncated cone of the first conductive element disposed near a bottom end of the microphone body;
a conductive cup surrounding the wide end of the cone or truncated cone of the first conductive element, and an insulating layer is located between the conductive cup and the wide end of the cone or truncated cone of the first conductive element. and
an RF amplifier connected to a first antenna feed-point connected to the first conductive element and a second antenna feed-point connected to the second conductive element.

2. The handheld wireless microphone as recited in claim 1 wherein and the second conductive element is a conductive frame for the microphone body.

3. The handheld wireless microphone as recited in claim 1 wherein antenna is effective across a frequency range of 470 MHz to 1525 MHz.

4. The handheld wireless microphone as recited in claim 1 further comprising a microphone head.

5. The handheld wireless microphone as recited in claim 4 further comprising a microphone head adapter.

6. The handheld wireless microphone as recited in claim 1 wherein there is no impedance matching circuit between output of the RF amplifier and feed-points to the dipole RF antenna.

7. The handheld wireless microphone as recited in claim 1 wherein radiation transmitted from the dipole RF antenna has a circular doughnut shaped directivity pattern where an equal radiation intensity results regardless of the radial orientation (rotation about the major axis) of the handheld microphone.

8. The handheld wireless microphone as recited in claim 7 further comprising an omnidirectional microphone head.

9. The handheld wireless microphone as recited in claim 2 wherein the microphone body includes a unitary outer shell made of plastic that contains the dipole RF antenna and the RF amplifier.

10. The handheld wireless microphone as recited in claim 1 wherein the RF amplifier is connected to the first antenna feedpoint on the first conductive element with a shielded cable in which a shield for the shielded cable is referenced to the voltage potential of the second antenna feedpoint.

11. The handheld wireless microphone as recited in claim 1 further comprising
a balancing counterweight placed within the cone or truncated cone forming the first conductive element at the lower end of the microphone body.

12. The handheld wireless microphone as recited in claim 11 further comprising means to retain the balancing weight snugly within cone or truncated cone forming the first conductive element at the lower end of the microphone body.

13. The handheld wireless microphone as recited in claim 11 wherein the balancing weight has a cone shape or a truncated cone shape.

14. The handheld wireless microphone as recited in claim 11 wherein the balancing weight is removable may be removed and interchanged with another balancing weight having a different mass, depending on the preferences of a user.

15. The handheld wireless microphone as recited in claim 1 further comprising
a balancing weight placed within the cone or truncated cone forming the first conductive element at the lower end of the microphone body; and
a plastic screw cap to retain the balancing weight within the cone or truncated cone forming the first conductive element at the lower end of the microphone body, wherein the conductive cup is embedded within said plastic screw cap.

16. The handheld wireless microphone as recited in claim 15 wherein the insulating layer located between the conductive cup and the wide end of the cone or truncated cone of the first conductive element comprises a plastic layer on the plastic screw cover between the conductive cup and the first conductive element when the screw cover is fully attached to the lower end of the microphone body.

17. The handheld wireless microphone as recited in claim 16 wherein the plastic screw cover is made of polycarbonate.

18. The handheld wireless microphone as recited in claim 14 further comprising a microphone head adapter which enables the microphone head to be interchanged with another microphone head compatible with the adapter.
